(19) United States
(12) Patent Application Publication
(10) Pub. No.: US 2007/0046508 A1
(43) Pub. Date: Mar. 1, 2007

(54) Sampling rate converter and a semiconductor integrated circuit

(76) Inventor: Naohiro Nishikawa, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/512,171

(22) Filed: Aug. 30, 2006

(30) Foreign Application Priority Data
Aug. 31, 2005 (JP) 2005-250852

(51) Int. Cl. H03M 7/00

(52) U.S. Cl. 341/61

(57) ABSTRACT

The present invention reduces the manufacturing cost of a sampling rate converter. The sampling rate converter disclosed herein comprises a buffer for buffering input data, a sampling rate converter core for converting a sampling rate of data output from the buffer, and a sampling rate conversion control unit capable of controlling sampling rate conversion by the sampling rate converter core. The sampling rate conversion control unit comprises a table of data for control of the sampling rate conversion by the sampling rate converter core and an input sampling rate calculating module which determines an input sampling rate for the sampling rate converter core by referring to the table, wherein the data for control in the table can be updated. A PLL circuit for sampling rate conversion is dispensed with and reducing the manufacturing cost of the sampling converter is achieved.

### CROSS-REFERENCE TO RELATED APPLICATION

The present application claims priority from Japanese application No. 2005-250852 filed on Aug. 31, 2005, the content of which is hereby incorporated by reference into this application.

### BACKGROUND OF THE INVENTION

The present invention relates to a sampling rate converter for converting input data sampled at a first sampling rate into output data sampled at a second sampling rate and a technique that is effectively applicable to an semiconductor integrated circuit for use in, for example, audio playback equipment and a digital broadcasting receiver.

Some method and apparatus for rectifying a sampling frequency deviation at a receiving end of asynchronous transmission of digital audio data are known (e.g., see Patent Document 1). According to this, a buffer memory 24 is provided at the receiving end for storing received data at a stage before being converted into analog and control of reading from the buffer is performed in a relationship to the received data amount stored in order to maintain the data amount stored in the buffer memory constant. One of means for implementing the above control is achieved such that a control unit 30 performs fine adjustment of a clock corresponding to a sampling frequency supplied by a clock generating circuit 29. However, a PLL circuit 22a in the receiver is disclosed, but sampling rate conversion is not performed.

A sampling rate converter internally including a phase locked loop (PLL) circuit is known (e.g., see Patent Document 2). According to this, the PLL circuit generates a signal corresponding to a multiplication of the sampling rate of input data and a conversion ratio between input and output data sampling rates is determined by that signal.

[Patent Document 1] Japanese Unexamined Patent Publication No. 2002-268662

[Patent Document 1] Japanese Unexamined Patent Publication No. 2002-77063

### SUMMARY OF THE INVENTION

According to the above-mentioned prior art, the precision and range of jitter rectification is determined by a multiple factor of sampling rate multiplication by the PLL circuit. However, according to examination made by the present inventor, is has been found that the PLL circuit requires an analog process and, if such PLL circuit is included in a semiconductor integrated circuit, both digital and analog processes are mixed, which necessitates an increase in the manufacturing cost. As for equipment for receiving digital broadcasting, a receiving error may cause missing data. In such cases, a silent frame may occur during frame sequence due to the missing data.

An object of the present invention is to reduce the manufacturing cost of a sampling rate converter.

An another object of the present invention is to provide a sampling rate converter capable of filling the gap of a silent frame occurred during frame sequence as a result of missing data due to a receiving error.

The above and other objects and novel features of the present invention will become apparent from the description of the present specification and the accompanying drawings.

Typical aspects of the invention disclosed herein will be summarized below.

One aspect of the present invention resides in a sampling rate converter comprising a buffer for buffering input data, a sampling rate converter core for converting a sampling rate of data output from the buffer, and a sampling rate conversion control unit capable of controlling sampling rate conversion by the sampling rate converter core. The sampling rate conversion control unit comprises a table of data for control of the sampling rate conversion by the sampling rate converter core and an input sampling rate calculating module which determines an input sampling rate for the sampling rate converter core by referring to the table, wherein the data for control in the table can be updated.

According to the above means, the input sampling rate calculating module determines an input sampling rate for the sampling rate converter core by referring to the table and the sampling rate converter core performs the sampling rate conversion, based on the input sampling rate obtained by the sampling rate converter core. This dispenses with a PLL circuit for sampling rate conversion and achieves reducing the manufacturing cost of a sampling rate converter.

The above data for control in the table may comprise values set in relation to the data amount buffered in the buffer. Because the data contained in the table can be updated, the data for control of sampling rate conversion can be changed flexibly, adaptive to system operation.

The above input sampling rate calculating module may be configured to refer to the table and read one of sampling rate adjustment values predefined, which is associated to the current data amount buffered in the buffer, and to obtain the input sampling rate for the sampling rate converter core, based on the adjustment value.

The above input data may be audio data.

The above input sampling rate calculating module may be configured including a function which, if a missing portion of the input data is detected, decreases the sampling rate for data preceding and data following the missing portion.

The sampling rate converter configured as above may be provided in a semiconductor integrated circuit.

In another aspect, a sampling rate converter is configured including a buffer for buffering input data, a sampling rate converter core for converting a sampling rate of data output from the buffer, and a sampling rate conversion control unit capable of controlling sampling rate conversion by the sampling rate converter core, wherein the sampling rate conversion control unit may be configured including a function to control the sampling rate conversion by the sampling rate converter core such that, if a missing portion of the input data is detected, the control unit decreases the sampling rate for data preceding and data following the missing portion.

The data preceding and the data following the above missing portion may be one frame of audio data, respectively.

Effect that will be achieved by typical aspects of the invention disclosed herein will be briefly described below.

By dispensing with a PLL circuit for sampling rate conversion, it is possible to reduce the manufacturing cost of a sampling rate converter.

### BRIEF DESCRIPTION OF THE DRAWINGS

FIG. 1 is a block diagram showing an example of a configuration of playback equipment to which a sampling rate converter of the present invention is applied.

FIG. 2 is a block diagram showing an example of a detailed configuration of the above sampling rate converter.

FIG. 3 is a diagram to explain a temporary buffer included in the above sampling rate converter.

FIG. 4 is a block diagram showing an example of a detailed configuration of the main portion of the above sampling rate converter.

FIG. 5 is a flowchart of calculation processing by an input sampling rate calculating module included in the above sampling rate converter.

FIG. 6 is a diagram to explain obtaining an FSN register value in the above sampling rate converter.

FIG. 7 is a characteristic graph showing a simulation result of sampling rate conversion by the above sampling rate converter.

FIG. 8 is another diagram to explain obtaining an FSN register value in the above sampling rate converter.

FIG. 9 is another characteristic graph showing a simulation result of sampling rate conversion by the above sampling rate converter.

FIG. 10 is a block diagram showing an example of a configuration of a digital broadcasting receiver to which a sampling rate converter of the present invention is applied.

FIG. 11 is a block diagram showing an example of a configuration of the sampling rate converter shown in FIG. 10.

FIG. 12 is a diagram to explain obtaining an FSN register value in the sampling rate converter shown in FIG. 10.

FIG. 13 is a flowchart of calculation processing by an input sampling rate calculating module included in the sampling rate converter shown in FIG. 10.

FIG. 14 is a characteristic graph showing a simulation result of sampling rate conversion by the sampling rate converter shown in FIG. 10.

FIG. 15 is a diagram to explain a receiving error and its remedy in the above digital broadcasting receiver.

### DETAILED DESCRIPTION OF THE PREFERRED EMBODIMENTS

### Embodiment 1

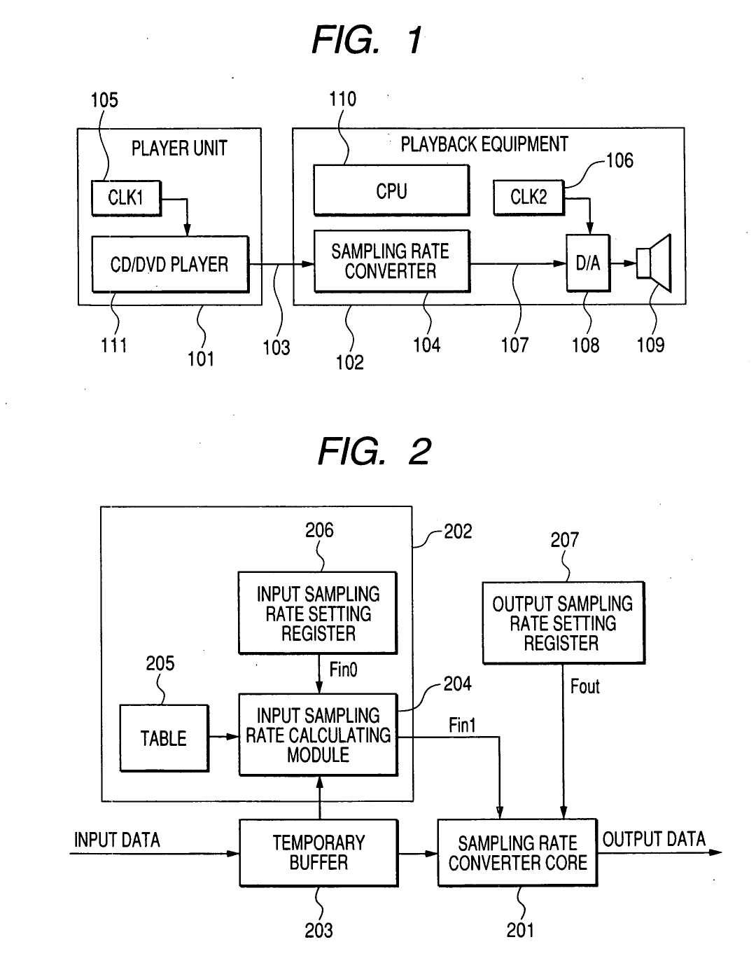

FIG. 1 shows playback equipment to which a sampling rate converter of the present invention is applied. The playback equipment 102 shown in FIG. 1 is for, but not limited to, making audio output based on audio signals 103 output from a player unit 101, and includes a sampling rate converter 104 for performing sampling rate conversion on input audio signals 103 and outputting audio signals 107 with the thus converted sampling rate, a clock generating circuit 106 for generating a clock signal CLK2, a digital/analog (D/A) converter circuit 108 for converting output data of the sampling rate converter 104 into analog signals, based on the clock signal CLK2, an audio output unit 109 which performs audio output in accordance with the analog signals output from the D/A converter circuit 108, and a central processing unit (CPU) 110 that takes overall control of operation of the playback equipment. The player unit 101 includes a clock generating circuit 105 for generating a clock signal CLK1 and a CD/DVD player 111 which outputs the audio signals 103 based on the clock signal CLK1. Here, the sampling rate converter 104 is provided as an LSI formed on a single semiconductor substrate such as a monocrystalline silicon substrate by a publicly known technique for fabricating a semiconductor integrated circuit.

FIG. 2 shows an example of a configuration of the sampling rate converter 104.

As shown in FIG. 2, the sampling rate converter 104 includes, but not limited to, a temporary buffer 203 capable of holding input data temporarily, a sampling rate converter core 201 for receiving output data from the temporary buffer 203 and carrying out sampling rate conversion, an input sampling rate conversion control unit 202 for control of sampling rate conversion by the sampling rate converter core 201, and an output sampling rate setting register 207 which enables setting of an output sampling rate.

The input sampling rate conversion control unit 202 includes a table 205 in which sampling rate adjustment values are tabulated, an input sampling rate setting register 206 which enables setting of an input sampling rate, and an input sampling rate calculating module 204 for calculating an input sampling rate Fin1. Here, the table 205 is formed by a register to hold data for sampling rate adjustment values. The data (table data) stored on this register can be updated, when appropriate, by the CPU 110, which is true for other registers and the like. For input sampling rate Fin1 calculation by the input sampling rate calculating module 204, output Fin0 of the input sampling rate setting register 206, the table 205, and the current data amount buffered in the temporary buffer 203 are referenced.

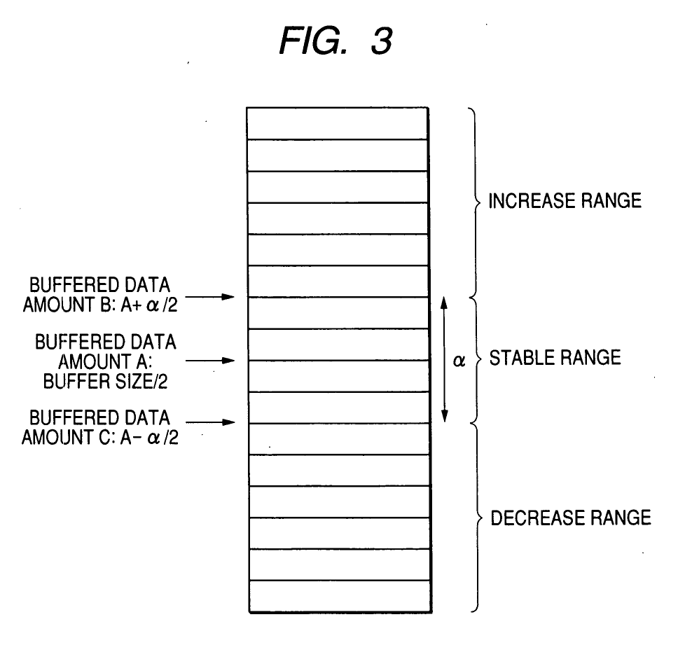

After data has been stored into the temporary buffer 203 up to buffered data amount A, namely, a half of the buffer size, as is shown in FIG. 3, the sampling rate converter core 201 is activated. Thereafter, the amount of data buffered in the temporary buffer 203 increases or decreases, depending on a ratio between the sampling frequency of input data to the temporary buffer 203 and the input sampling frequency to the sampling converter core 201. In the present embodiment, a stable range, increase range, and decrease range of the temporary buffer 203 are defined, as is shown in FIG. 3. Further, “α” that determines the stable range is a constant that is determined by a ratio between a maximum value of input sampling rate to the sampling rate converter and a maximum value of output sampling rate. This “α” is expressed by Equation (1).
α=Maximum value of input sampling rate/Minimum value of output sampling rate (round up fractions) (1)

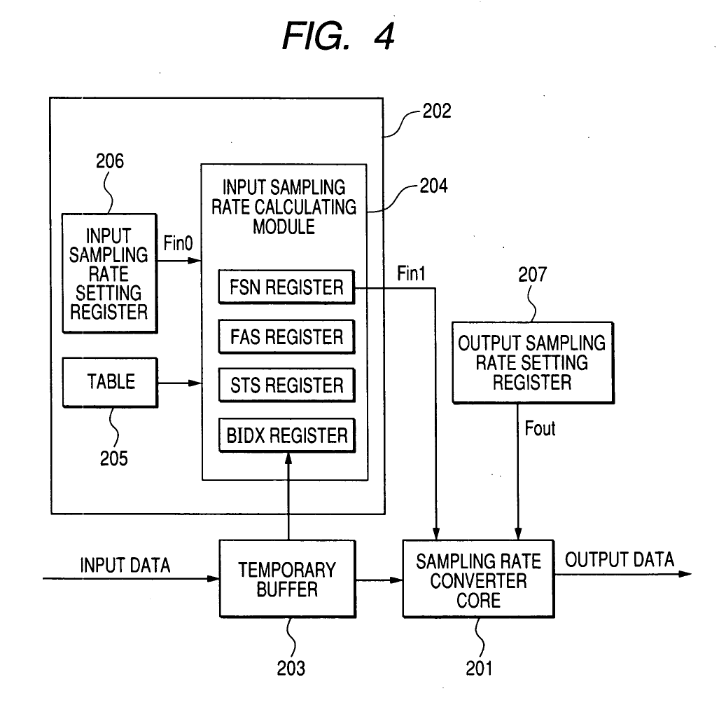

FIG. 4 shows an example of a configuration of the input sampling rate calculating module 204.

The input sampling rate calculating module 204 includes, but not limited to, an FSN register capable of holding the current adjustment value of sampling rate, an FAS register capable of holding the initial adjustment value of sampling rate, an STS register capable of holding status, a BIDX register capable of holding an index value (data for the current data amount buffered) of the temporary buffer 203, and an arithmetic unit (not shown) which performs predetermined calculation processing, using the output values of the above registers.

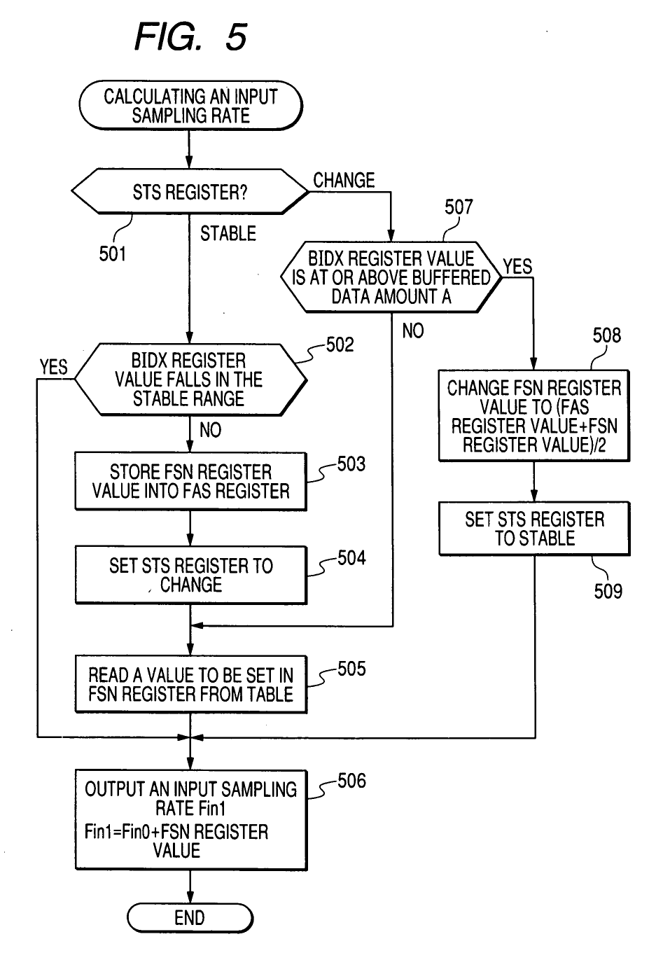

FIG. 5 shows a flow of calculation processing by the input sampling rate calculating module 204.

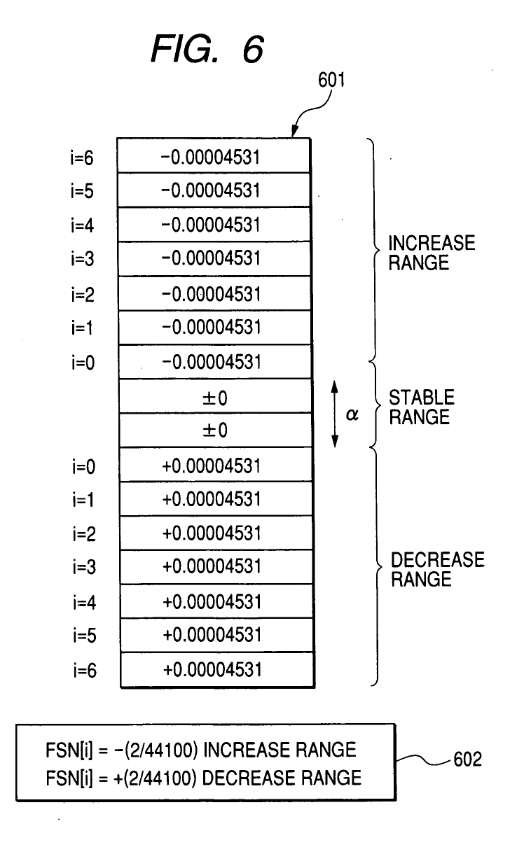

First, it is determined whether status “Change” or “Stable” is held in the STS register (step 501). As determined at this step, if the Stable status is held in the STS register, it is then determined whether the buffer index value held in the BIDX register falls within the stable rage (see FIG. 3) (502). As determined at this step, if the buffer index value does not fall within the stable rage (NO), the current adjustment value of sampling rate held in the FSN register is stored into the FAS register (step 503) and the status held in the STS register is set to “Change” (step 504). Then, a new value to be set in the FSN register (an adjustment value FNS of sampling rate) is read from the table 205 (step 505). At this time, the adjustment values contained in the table 205 are set like those exemplified in a column 601 in FIG. 6. Because values in the stable range do not need to be adjusted, they are ±0. Number “i” denotes a degree of deviation from the stable range. The larger this number, the larger will be its associated adjustment value. By using this deviation degree as an index, an adjustment value is read from the table. A new value (adjustment value) to be set in the FSN register is negative signed, if the buffer index value held in the BIDX register falls within the increase range, and positive signed, if the buffer index value held in the BIDX register falls within the decrease range. Although an FSN register value can also be obtained such a manner in which the arithmetic unit executes calculation according to a calculating formula 602 in FIG. 6, reference to the table as above is a faster way of getting an FSN register value.

Then, adding the output value Fin0 of the input sampling rate setting register 206 and the FSN register value is performed by the arithmetic unit not shown, as in Equation (2). A result of the addition is output as an input sampling rate Fin1 from the input sampling rate calculating module 204.
Fin1=Fin0+FSN register value (2)

As determined at the above step 501, if the “Change” status is held in the STS register, it is determined whether the BIDX register value (buffer index) is at or above the buffered data amount A (a half of the buffer size). As determined at this step, if the BIDX register value is less than the buffered data amount A (NO), the process goes to the above step 505 where an FSN register value is read from the table 205. As determined at the above step 507, otherwise, if the BIDX register value is at or above the buffered data amount A (YES), the FSN register value is changed to (FAS register value+FSN register value)/2 (508). The status held in the STS register is set to “Stable” (step 509). The process goes to the above step 506 where an input sampling rate Fin1 is calculated and output. As determined at the above step 502, if the buffer index value falls within the stable range (YES), the process goes to the above step 506 where an input sampling rate Fin1 is calculated and output. The thus obtained input sampling rate Fin1 is transferred to the sampling rate converter core 201.

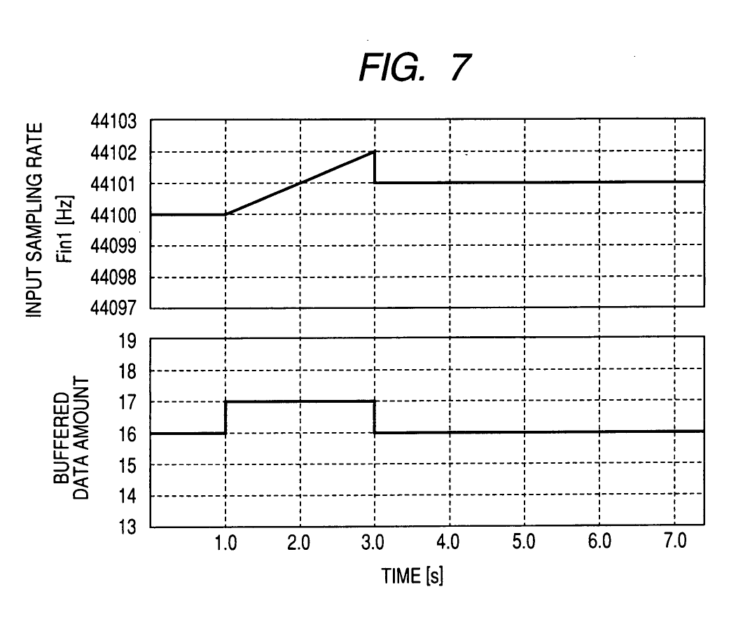

FIG. 7 shows a simulation result of sampling rate conversion by the sampling rate converter of the first embodiment. With an increase of the data amount buffered in the temporary buffer 203, the input sampling rate is adjusted to rise accordingly, so that the data amount buffered in the temporary buffer 203 is stabilized.

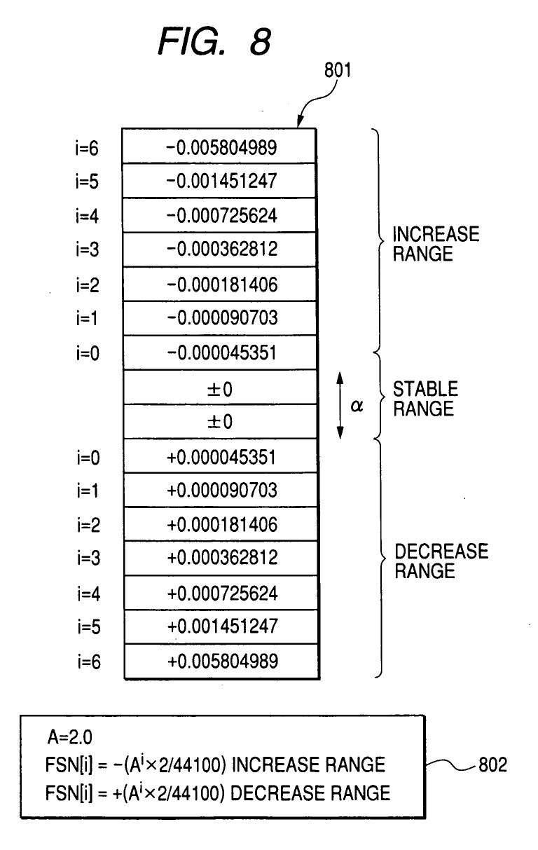

In the configuration shown in FIG. 1, an instance is then discussed where audio data sampled at 44.1 kHz and audio data sampled at 48 kHz are mixed as the output of the player unit 105 is discussed. For adjustment of such audio data, it is advisable to change the contents of the table 205 to those derived from an exponential function. An example of the table 205 structure in this case contains adjustment values like those exemplified in a column 801 in FIG. 8. By using the exponential function like this example, the table can be adapted to extend the dynamic range of input sampling rates and reduce the convergence time. An FSN register value can also be obtained by executing calculation according to a calculating formula 602 in FIG. 8.

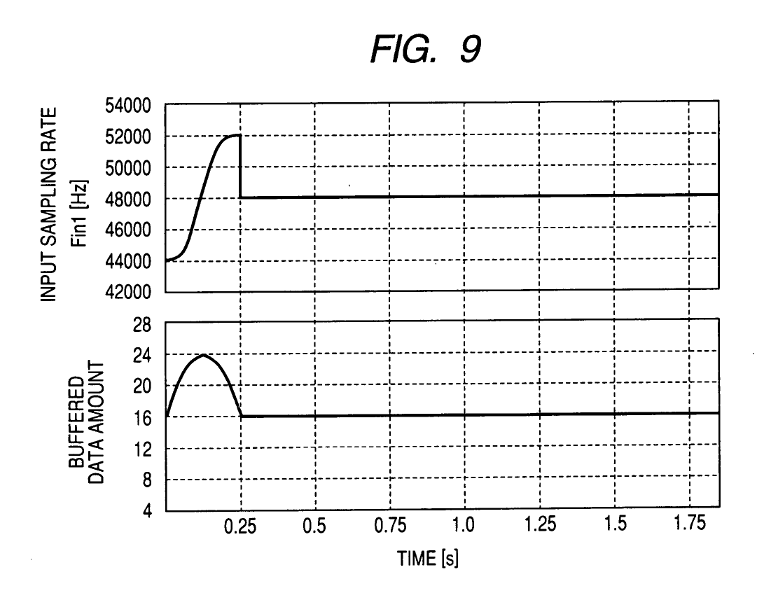

FIG. 9 shows a simulation result of sampling rate conversion by which the sampling rate of input audio data was altered from 44000 Hz to 48000 Hz. By the alteration of the sampling rate to 48000 Hz before and at a time point of 0.25 s, the buffered data amount is stabilized.

According to the foregoing embodiment, the following effects can be obtained.

(1) The sampling rate of the input audio signals 103 is generated from the clock signal CLK1 and the sampling rate of the output audio signals 107 is generated from the clock signal CLK2. Both clock signal CLK1 and clock signal CLK2 may suffer from a frequency error (jitter). The effect of the jitter may cause an underflow or overflow in the D/A converter. Such underflow or overflow may produce audible noise during audio playback. However, in the first embodiment, the sampling rate converter 102 is able to reduce the effect of the jitter. A ratio of sampling rate conversion is determined in such a manner that input data is buffered in the temporary buffer 203 and an input sampling rate is determined, based on the buffered data amount. By using the exponential function to determine this, enhancing the jitter rectification precision and extending the range of the sampling rate converter can be achieved.

(2) The cost of manufacturing an IC chip in which digital and analog circuits are mixed is high. Because the sampling rate converter described above dispenses with an analog PLL circuit, its manufacturing cost can be reduced.

(3) An FSN register value to be used in calculating an input sampling rate by the input sampling rate calculating module 204 can be directly read from the table 205. Thus, the FSN register value can be obtained in a shorter time than when it is obtained by arithmetic processing of the arithmetic unit.

(4) An FSN register value to be used in calculating an input sampling rate by the input sampling rate calculating module 204 can be directly read from the table 205. By updating the contents of the above table, the data for control of sampling rate conversion can be changed flexibly, adaptive to system operation. According to input sampling rate conversion control requirements, a jitter elimination range can be set or changed.

### Embodiment 2

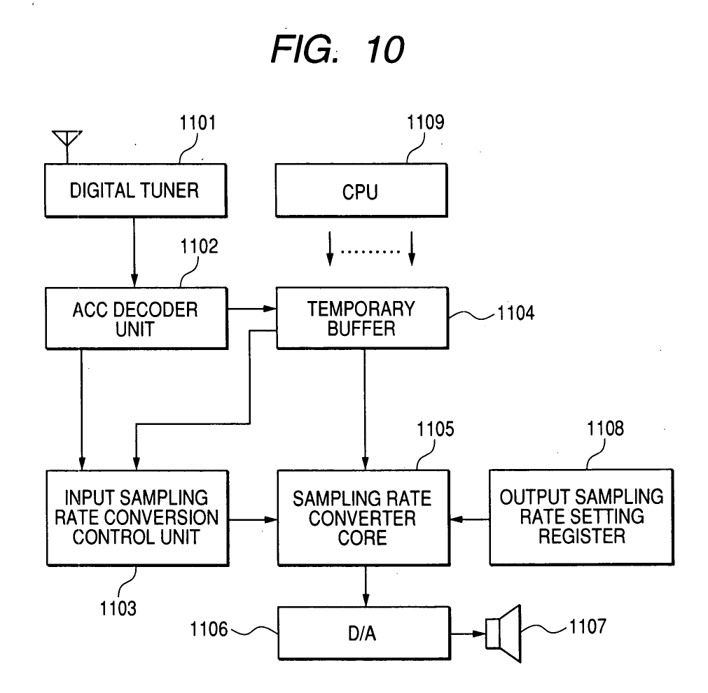

FIG. 10 shows a digital broadcasting receiver to which a sampling rate converter of the present invention is applied.

The digital broadcasting receiver shown in FIG. 10 includes, but not limited to, a digital tuner 1101 for receiving digital broadcasting, an AAC decoder unit 1102 for decoding received data, a temporary buffer 1104 for temporarily holding output data from the AAC decoder unit 1102, a sampling converter core 1105 for performing sampling rate conversion on input data, an output sampling rate setting register 1108 for setting an output sampling rate, an input sampling rate conversion control unit 1103 for control of input sampling rate conversion, based on missing frame information from the AAC decoder unit 1102 and the current data amount buffered in the temporary buffer 1104, a D/A converter circuit 1106 for converting output data from the sampling rate converter core 1105 into analog signals, an audio output unit 1107 which performs audio output in accordance with the analog signals output from the D/A converter circuit 1106, and a CPU 1109 that takes overall control of operation of the receiver. Here, the temporary buffer 1104, the sampling rate converter core 1105, the output sampling rate setting register 1108, and input sampling rate conversion control unit 1103 can be formed on a single semiconductor substrate such as a monocrystalline silicon substrate by a publicly known technique for fabricating a semiconductor integrated circuit.

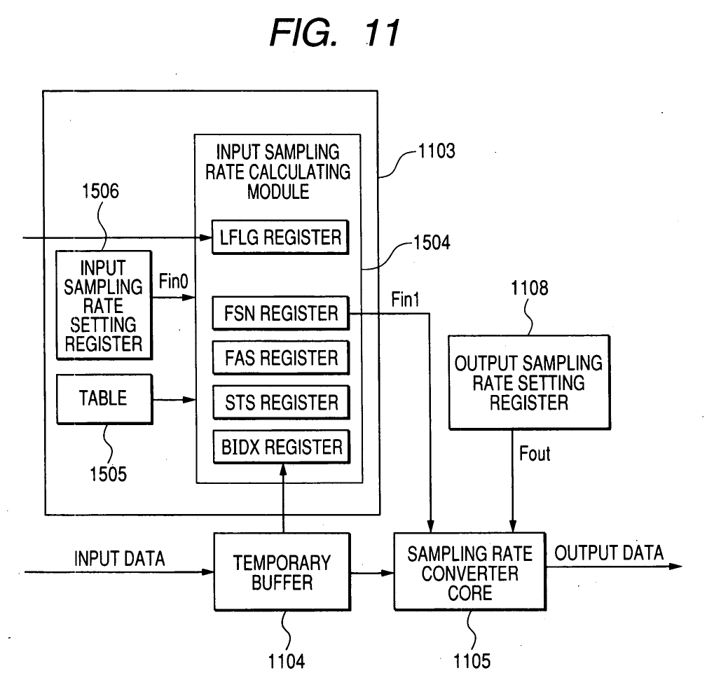

FIG. 11 shows an example of a configuration of the input sampling rate conversion control unit 1103.

As shown in FIG. 11, the input sampling rate conversion control unit 1103 includes, but not limited to, a table 1505 in which sampling rate adjustment values are tabulated, an input sampling rate setting register 1506 which enables setting of an input sampling rate, and an input sampling rate calculating module 1504 for calculating an input sampling rate Fin1. For input sampling rate Fin1 calculation by the input sampling rate calculating module 1504, output Fin0 of the input sampling rate setting register 1506, the table 1505, and the current data amount buffered in the temporary buffer 1104 are referenced. The input sampling rate calculating module 1504 includes, but not limited to, an LFLG register capable of holding information indicating whether a missing frame occurs, an FSN register capable of holding the current adjustment value of sampling rate, an FAS register capable of holding the initial adjustment value of sampling rate, an STS register capable of holding status, a BIDX register capable of holding an index value (the current data amount buffered) of the temporary buffer 1104, and an arithmetic unit (not shown) which performs predetermined calculation processing, using the output values of the above registers.

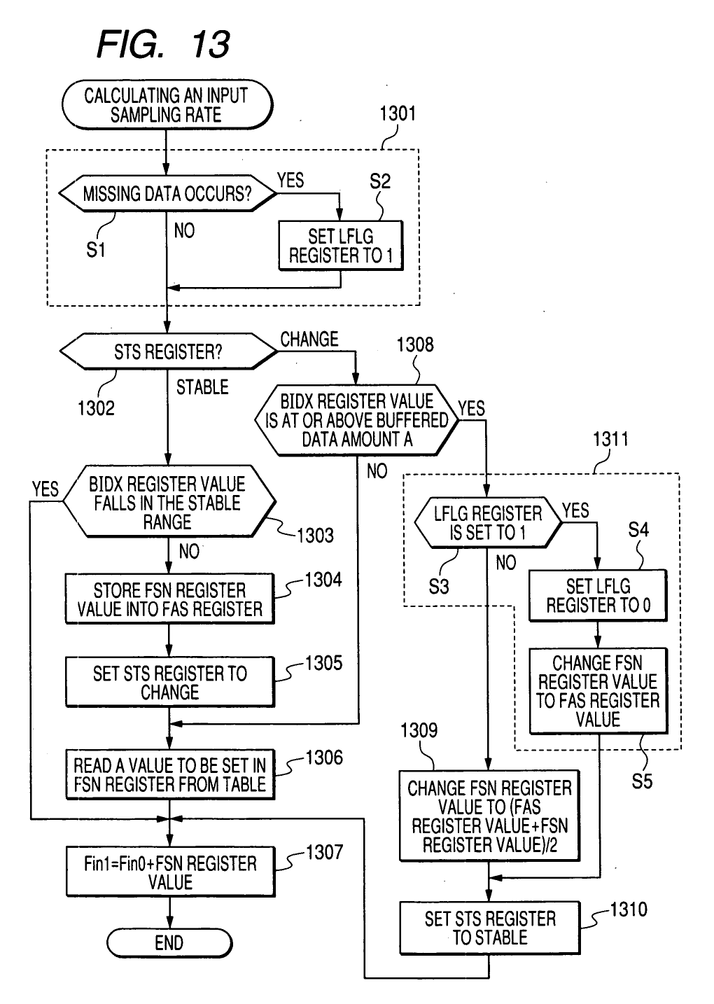

FIG. 13 shows a flow of calculation processing by the input sampling rate calculating module 1504.

Although the procedure for obtaining an input sampling rate Fin1 is the same as described in FIG. 5, a significant difference from the foregoing flowchart lies in that this flowchart includes a step 1301 for determining whether missing data occurs and a step 1311 to be executed upon detecting missing data.

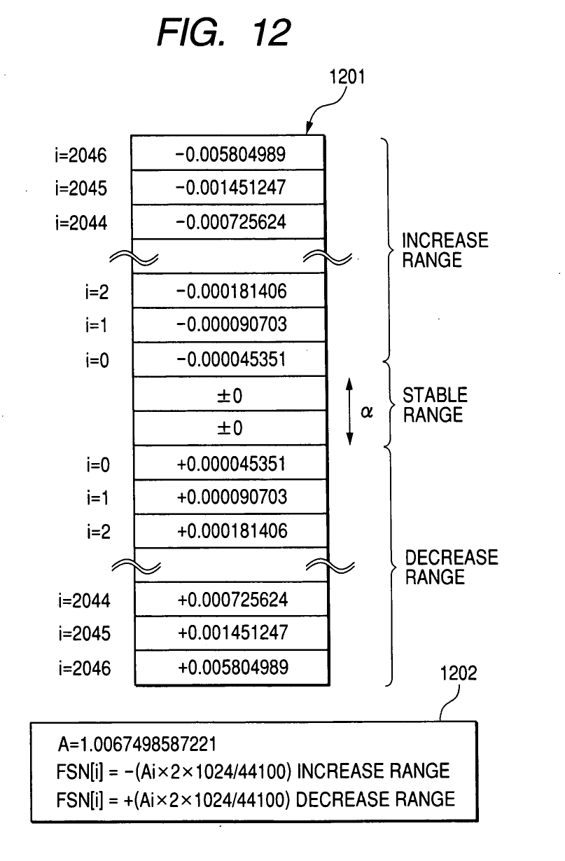

The step 1301 for determining whether missing data occurs comprises a step (S1) of determining whether a missing frame occurs and a step (S2) of setting a logical value of “1” in the LFLG register, if a missing frame occurs (YES), as determined at the preceding step. After the execution of this step 1301 for determining whether missing data occurs, it is determined whether status “Change” or “Stable” is held in the STS register (step 1302). As determined at this step, if the Stable status is held in the STS register, it is then determined whether the buffer index value held in the BIDX register falls within the stable rage (1303). As determined at this step, if the buffer index value does not fall within the stable rage (NO), the current adjustment value of sampling rate held in the FSN register is stored into the FAS register (step 1304) and the status held in the STS register is set to “Change” (step 1305). Then, a new value to be set in the FSN register (an adjustment value FNS of sampling rate) is read from the table 1505 (step 1306). At this time, the adjustment values contained in the table 1505 are set like those exemplified in a column 1201 in FIG. 12. A new value to be set in the FSN register is negative signed, if the buffer index value held in the BIDX register falls within the increase range, and positive signed, if the buffer index value held in the BIDX register falls within the decrease range. An FSN register value can also be obtained by executing calculation according to a calculating formula 1202 in FIG. 12. Then, adding the output value Fin0 of the input sampling rate setting register 1506 and the FSN register value is performed by the arithmetic unit not shown, and a result of the addition is output as an input sampling rate Fin1 from the input sampling rate calculating module 1504.

As determined at the above step 1302, if the “Change” status is held in the STS register, it is determined whether the BIDX register value (buffer index) is at or above the buffered data amount A (a half of the buffer size). As determined at this step, if the BIDX register value is less than the buffered data amount A (NO), the process goes to the above step 1306 where an FSN register value is read from the table 1505. As determined at the above step 1308, otherwise, if the BIDX register value is at or above the buffered data amount A (YES), the process goes to the step 1311 to be executed upon detecting-missing data. This step 1311 to be executed upon detecting missing data comprises a step (S3) of determining the LFLG register is set to a logical value of “1”, a step (S4) of setting the LFLG register to a logical value of “0” if the LFLG register is set to a logical value of “1” (YES), as determined at the preceding step, and a step (S5) of changing the FSN register value to the FAS register value. If it is determined that the LFLG register is not set to a logical value of “1” (NO), the FSN register value is changed to (FAS register value+FSN register value)/2 (1309). Then, the status held in the STS register is set to “Stable” (step 1310) and the process goes to the above step 1307 where an input sampling rate Fin1 is calculated and output. As determined at the above step 1303, if the buffer index value falls within the stable range (YES), the process goes to the above step 1307 where an input sampling rate Fin1 is calculated and output.

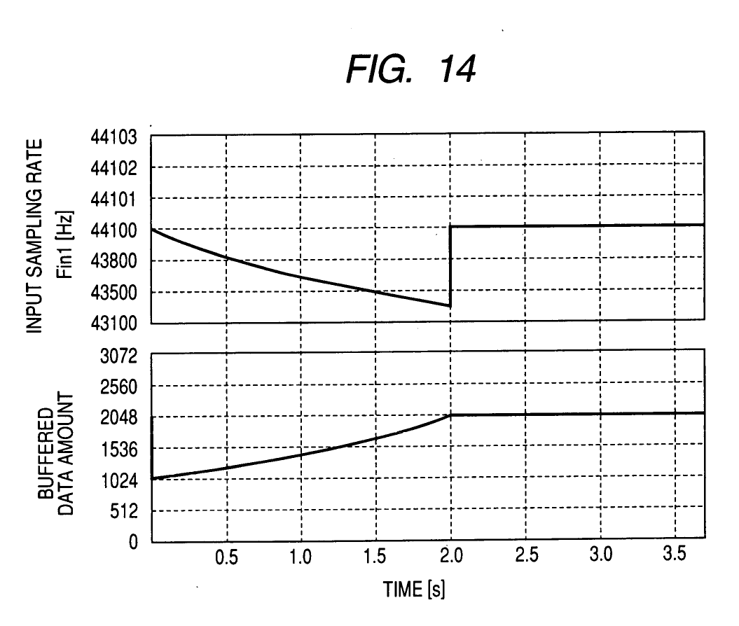

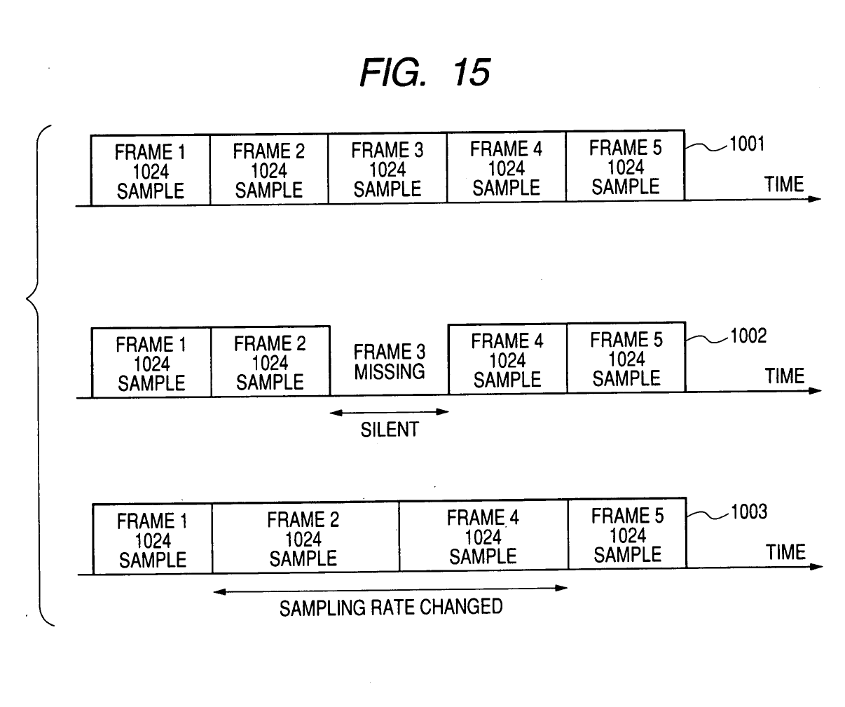

FIG. 14 shows a simulation result of sampling rate conversion, when missing data occurs, that is, a frame of 1024 samples is missing.

The input sampling rate is decreased between time points 0 s and 2.0 s. This extends the periods of both frames preceding and following the missing frame, thereby filling the gap of the silent frame during frame sequence due to the missing data. For example, in FIG. 15, reception of a normal frame sequence of audio data is shown as denoted by 1001, whereas a frame sequence in error, in which one frame of data is missing, is shown as denoted by 1002. Even if such error frame sequence is received, by decreasing the input sampling rate as above, the periods allowed for reproducing both frames preceding and following the missing frame are extended to fill the gap of the silent frame due to the missing data, as denoted by 1003 in FIG. 15, thereby noise trouble is eliminated.

According to the foregoing embodiment, the following effects can be obtained.

(1) For the digital broadcasting receiver shown in FIG. 10, similarly, a ratio of sampling rate conversion is determined in such a manner that input data is buffered in the temporary buffer 1104 and an input sampling rate is determined, based on the buffered data amount. Therefore, the same effects as noted for the playback equipment 106 shown in FIG. 1 can be obtained.

(2) Even if a missing data frame is received by the digital broadcasting receiver, by decreasing the input sampling rate, the periods allowed for reproducing both frames preceding and following the missing frame are extended to fill the gap of the silent frame due to the missing data, as denoted by 1003 in FIG. 15, thereby noise trouble is eliminated.

While the invention made by the present inventor has been described specifically hereinbefore, based on the foregoing embodiments, the present invention is not limited to the described embodiments and various changes may be made without departing from the gist of the invention.

For instance, the technique for filling the gap of a silent frame during frame sequence due to missing data, which is particularly effected in the second embodiment, can be applied in the playback equipment 102 of the first embodiment.

The above-mentioned table may be created through the use of a nonvolatile memory such as a flash memory.

While, in the foregoing description, the invention made by the present inventor has been explained with regard to the instances of its application to the playback equipment and the digital broadcasting receiver, which are regarded as typical examples in the background usage field of the invention, the present invention is not so limited and can widely be applied to various types of electronic equipment.

The present invention can be applied on the assumption that sampling rate conversion is at least performed.

1. A sampling rate converter comprising:
a buffer for buffering input data;
a sampling rate converter core for converting a sampling rate of data output from said buffer; and
a sampling rate conversion control unit capable of controlling sampling rate conversion by said sampling rate converter core,
said sampling rate conversion control unit comprising:
a table for storing data for control of the sampling rate conversion by said sampling rate converter core; and
an input sampling rate calculating module which determines an input sampling rate for said sampling rate converter core by referring to said table,
wherein said data for control in said table can be updated.

2. The sampling rate converter according to claim 1, wherein said data for control in said table comprises values set in relation to the data amount buffered in said buffer.

3. The sampling rate converter according to claim 2, wherein said input sampling rate calculating module refers to said table and reads one of sampling rate adjustment values predefined, which is associated to the current data amount buffered in said buffer, and obtains the input sampling rate for said sampling rate converter core, based on the adjustment value.

4. The sampling rate converter according to claim 1, wherein said input data is audio data.

5. The sampling rate converter according to claim 1, wherein said input sampling rate calculating module includes a function which, when a missing portion of said input data is detected, decreases the sampling rate for data preceding and data following said missing portion.

6. A semiconductor integrated circuit formed over a single semiconductor substrate, including the sampling rate converter as recited in claim 1.

7. A sampling rate converter comprising:
a buffer for buffering input data;
a sampling rate converter core for converting a sampling rate of data output from said buffer; and
a sampling rate conversion control unit capable of controlling sampling rate conversion by said sampling rate converter core,
wherein said sampling rate conversion control unit controls the sampling rate conversion by said sampling rate converter core such that, when a missing portion of said input data is detected, the control unit decreases the sampling rate for data preceding and data following said missing portion.

8. The sampling rate converter according to claim 7, wherein the data preceding and the data following said missing portion are one frame of audio data, respectively.
